(19) United States
(12) Patent Application Publication
(10) Pub. No.: US 2026/0135349 A1
(43) Pub. Date: May 14, 2026

(54) FREQUENCY TUNABLE SCANNING LASER

(71) Applicant: BAE Systems Information and Electronic Systems Integration Inc., Nashua, NH (US)

(72) Inventors: Craig C. Price, Manchester, NH (US); Zakary N. Burkley, Amherst, NH (US)

(73) Assignee: BAE Systems Information and Electronic Systems Integration Inc., Nashua, NH (US)

(21) Appl. No.: 18/946,427

(22) Filed: Nov. 13, 2024

(51) Int. Cl. H01S 5/14; G02F 1/29; H01S 5/00; H01S 5/024; H01S 5/0687

(52) U.S. Cl. CPC H01S 5/141; G02F 1/293; H01S 5/02415; H01S 5/0687; H01S 5/005

(57) ABSTRACT

A frequency tunable scanning laser system includes: an external cavity diode laser (ECDL) configured to output laser light; an electro-optic deflector (EOD) being at least partially transparent and configured to deflect the laser light passing through the EOD; and a fixed, wavelength-sensitive diffraction grating configured to reflect at least a portion of the laser light deflected by the EOD back to the ECDL via the EOD at a tunable frequency. The tunable frequency is a function of an angle of incidence of the laser light on the grating, and the angle of incidence is based on an amount of deflection of the laser light by the EOD. In some examples, the EOD includes a lithium tantalate (LTA) crystal or a similar crystal. This configuration enables a low-phase noise laser system that is both steady and quickly tunable in frequency.

### FIELD OF DISCLOSURE

The present disclosure relates to lasers, and more particularly, to a tunable, scanning laser.

### BACKGROUND

Spread spectrum, or frequency hopping, is a technique for transmitting and receiving signals over a variable carrier frequency. With this technique, the carrier frequency is rapidly and repeatedly changed, or hopped, to a particular sub-frequency within a band or a large spectrum of frequencies, thereby spreading the content of the signal across a wide bandwidth. Both the transmitter and receiver are simultaneously tuned to the same frequency according to, for example, a pseudo-random sequence known to the transmitter and receiver. Frequency hopping has various applications, such as for reducing the effects of frequency-specific interference, such as signal jamming, and to increase the difficulty of signal interception, such as by using a secret key to encrypt the hop sequence used by the transmitter and receiver.

Implementation of frequency hopping is dependent on the components used to generate and process the signal. Certain components or systems may, for example, operate too slowly to be effectively or suitably used in certain high speed hopping applications. Therefore, non-trivial issues remain with respect to spread spectrum communications techniques.

### BRIEF DESCRIPTION OF THE DRAWINGS

FIG. 1 is a block diagram of a communication environment, in accordance with an example of the present disclosure.

FIG. 2 shows the relationship between wavelength and frequency for the communication system of FIG. 1, in accordance with an example of the present disclosure.

FIG. 3 is a block diagram of a portion of an RF communication system, in accordance with an example of the present disclosure.

FIG. 4 is a block diagram of the frequency tunable scanning laser system of FIG. 1, in accordance with an example of the present disclosure.

FIG. 5 is a graph showing an example output of the frequency tunable scanning laser system of FIG. 4, in accordance with an example of the present disclosure.

FIG. 6 is a block diagram of a communications method using the frequency tunable scanning laser system of FIG. 4, in accordance with an example of the present disclosure.

Although the following detailed description refers to illustrative examples, many alternatives, modifications, and variations thereof will be apparent in light of this disclosure.

### DETAILED DESCRIPTION

A frequency tunable scanning laser system is disclosed. In an example of the present disclosure, the system includes: an external cavity diode laser (ECDL) configured to output laser light; an electro-optic deflector (EOD) being at least partially transparent and configured to deflect the laser light passing through the EOD; and a fixed, wavelength-sensitive diffraction grating configured to reflect at least a portion of the laser light deflected by the EOD back to the ECDL via the EOD at a tunable frequency. The tunable frequency is a function of an angle of incidence of the laser light on the grating, and the angle of incidence is based on an amount of deflection of the laser light by the EOD. In some examples, the EOD includes a lithium tantalate (LTA) crystal or a similar crystal. This configuration enables a low-phase noise laser system that is both steady and quickly tunable in frequency.

In some examples, the ECDL includes a gain chip with dual partially reflecting facets. In some examples, the system includes a collimating lens configured to collimate the laser light. In some examples, the ECDL is configured to output the laser light at each of a plurality of different tunable frequencies. In some examples, the system includes a controller configured to control the tunable frequency by causing the EOD to vary the amount of deflection of the laser light passing through the EOD. The controller is configured to output a voltage to the EOD, wherein the amount of deflection of the laser light passing through the EOD is a function of the voltage. In some examples, the EOD crystal can maintain a steady, fixed amount of deflection (e.g., the crystal is stable during deflection).

In accordance with an example of the present disclosure, one or more semiconductor lasers can be used in spread spectrum applications, where the carrier frequency is rapidly changed. It is appreciated that the selection of the laser(s) can affect the effectiveness and reliability of the communications. For instance, certain external cavity diode lasers (ECDLs) use thermal mass or mechanical motion of the reflection of the laser to tune the cavity length, thereby tuning the wavelength of the signal across nanometers of spectrum. Such lasers may have settling times in the tens of seconds or milliseconds for mechanical motion of the laser path. However, such long settling times may not be suitable for certain frequency hopping applications because they limit the maximum rate at which hopping can reliably occur. If the hop rate is too slow for a given application, the data rate of the communications may be adversely impacted. Furthermore, the stability of the laser, once settled, has an effect on the usability of the laser for some applications. If, for example, the laser frequency drifts, the receiver may not be able to lock onto the signal for the duration of the transmission at a given frequency. Or, if the phase noise of the laser is high, then some communication schemes cannot be performed at low RF signal power levels.

For at least the foregoing reasons, in certain applications, the laser should have both fast tuning, achieved via fast settling, stability, and low phase noise. For instance, a laser having such properties is useful for spread spectrum communications applications where the frequency changes rapidly, necessitating fast settling times and stability for each hop in the sequence.

In an example of the present disclosure, a laser communication system includes one external cavity diode laser (ECDL) in combination with an electro-optic deflector (EOD). The ECDL is a tunable frequency diode laser with one or more external optical elements, such as diffraction gratings or mirrors. The diode laser is a semiconductor device that emits coherent (laser) light.

The EOD is a device for changing the direction of the laser light travelling between the laser and the external optical elements using an electric field, generally at small deflection angles with high accuracy. For example, the EOD can include a crystal through which the laser light passes. Certain crystals deflect the angle of the laser beam as a function of the voltage applied to the crystal.

The crystal can change the angle of the laser beam quickly as the voltage applied to the crystal changes, for example, on the order of nanoseconds for certain types of crystals. The amount of the deflection and the stability of the deflection depends on the type of crystal. In an example of the present disclosure, the ECDL can include a fixed grating and an EOD with a lithium tantalate (LTA) crystal or any other crystal with stability, speed, and selection (scanning) properties similar to, or better than, LTA. In some examples, the crystal, such as LTA, is transparent in the Near Infrared Spectroscopy (NIR) (e.g., transparent from 0.5 micros to 5 microns), have a large electro-optic (EO) coefficient (e.g., R33=30.4), and have an EO coefficient that is stable over time against a large, applied direct current (DC) voltage (e.g., +/−450 volts). In an example, using LTA, the laser can change wavelengths of 1.7 nm, repeatedly return to the frequency from which it hopped with hysteresis not greater than the drift of an unlocked, free-running ECDL within 30 MHz, and make hop transitions with a 10% to 90% rise time faster than 560 nano seconds. The laser can also sustain fixed DC offset deflections, maintaining stable operation on the order of minutes with a frequency drift of less than 1.5 MHz/second.

In some examples, a signal is encoded in the laser light using a frequency-hopping spread spectrum (FHSS) technique. FHSS causes data to be encoded on signals at several different carrier frequencies across a wide band of frequencies. The selection of a given carrier frequency is controlled by a code known to the transmitter (e.g., a communication system) and the receiver (e.g., a frequency tunable scanning laser system). A hopping period defines the amount of time between changes (hops) in the carrier frequency (tone). By rapidly switching (hopping) between different carrier frequencies (tones) according to the code, the signal is less likely to be intercepted or jammed or unlikely to be intercepted or jammed for more than one hopping period. In some examples, the signal is encrypted to further secure the incoming signal from unauthorized access.

Communication System with Frequency Tuning Scanning Laser

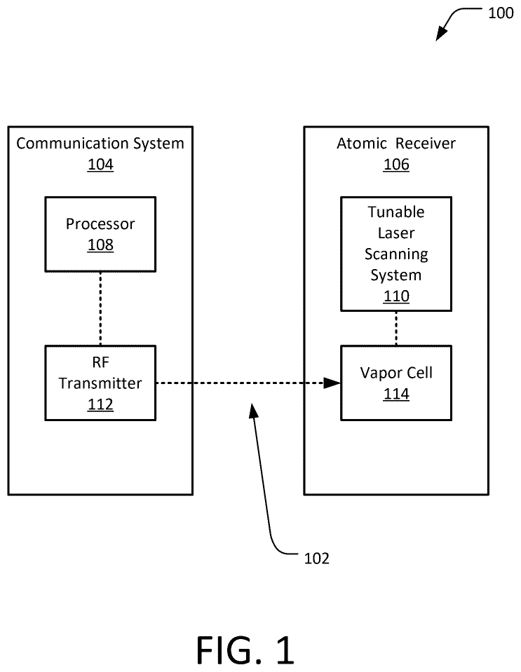

FIG. 1 is a block diagram of a communication environment 100, in accordance with an example of the present disclosure. The communication environment 100 includes a communication system 104 and an atomic receiver 106 utilizing a tunable laser scanning system 110. Signals 102 can be communicated from the communication system 104 to the atomic receiver 106 with the tunable laser scanning system 110. The signals 102 can be modulated or otherwise encoded with data representing information to be communicated between from the communication system 104 to the atomic receiver 106 via radio frequency (RF).

The communication system 104 includes a processor 108 and an RF transmitter 112. The atomic receiver 106 includes the tunable laser scanning system 110 and a vapor cell 114. The processor 108 is configured to process electrical signals including the information to be communicated by the RF transmitter 112. A source of the information can be, for example, a computing system or a platform for the communication system 104, such as an aircraft, a satellite, a ship, a vehicle, or a ground station. A destination of the information can be, for example, another computing system or another platform for the atomic receiver 106. For instance, the communication system 104 and the atomic receiver 106 are not co-located; that is, the communication system 104 and the atomic receiver 106 are separated by some amount of space, can operate independently of each other, and are not connected by any physical signal transmission lines.

The signal 102 impinges the vapor cell 114 of the atomic receiver 106, which is configured to extract information from the signal 102 using the vapor cell 114 and the frequency tunable scanning laser system 110. For example the laser light hops among different frequencies to read out the RF signal, where the frequency of the signal 102 is changed over the course of the communication. The frequency tunable scanning laser system 110 is described in further detail below.

The laser emitted from the frequency tunable scanning laser system 110 interrogates atoms within the vapor cell 114. To detect the signal 102 over a broad frequency range, the frequency of the laser is changed to an appropriate corresponding frequency within the range.

A precision laser system in accordance with an example of the present disclosure can change wavelengths over multiple nanometers in, for example, less than 1 microsecond, corresponding to RF sensing over, for example, 10 MHz-40 GHz. In this example, the precision laser system includes a narrow linewidth laser in which all of the spectral content of the laser light exists in a very narrow spectral band (that is, the phase noise of the laser is low). The precision laser system in accordance with an example of the present disclosure implements a narrow linewidth laser source that can be rapidly switched between several wavelengths rather than a conventional swept light source. A benefit of quickly changing the frequencies using such a narrow linewidth laser is to enable monitoring signals over a large frequency range in a relatively short amount of time, which is more difficult to achieve with a swept light source due to delays when changing frequencies and deterioration of the laser beam profile caused by time-dependent charge distribution.

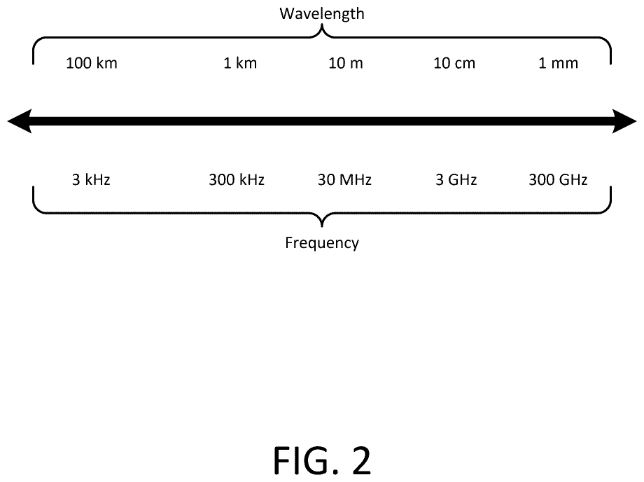

FIG. 2 shows the relationship between wavelength and frequency, as a reference for further discussion. As can be seen, the wavelength of a signal decreases as frequency increases, and vice versa. That is, low frequency signals have longer wavelengths than high frequency signals. In an example of the present disclosure, a FHSS or other frequency hopping application using techniques described herein may include hopping (changing) between two frequencies in less than 10 microseconds, in some examples, and in less than 1 microsecond, in some other examples. For example, during transmission of a hopped signal, the frequency can change from 3 kHz to 300 GHz, and remain stable at 300 GHz, for 10 microseconds. Such hopping requires changing the frequency of the laser in the atomic receiver 106 multiple times over the course of a signal transmission. For instance, hopping an RF carrier from 10 kHz to 40 GHz may require the laser of the atomic receiver 106 to change over 5 nm.

Frequency Tunable Scanning Laser System with Multiple Lasers

In accordance with an example of the present disclosure, a communication system includes several lasers (e.g., two, three, four, or more) each having a fixed or variable frequency, where each laser can operate at a different frequency. During frequency hopping, the system switches between the several lasers each operating at different frequencies. Because each laser operates at a different frequency, the laser can be set at the desired hop frequency, or permanently set to a specific frequency, before the system switches to that laser, thus reducing or eliminating the settling time when the system hops between frequencies. Such a system may have relatively high size, weight, power, and cost (SWaP-C) for a given application. However, other examples of the present disclosure such as described below reduce the number of lasers and replace them with fast switching, reducing SWAP-C.

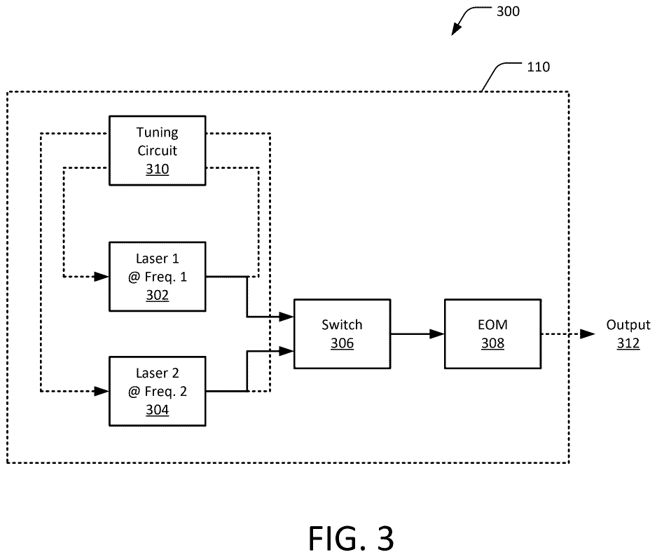

An example of such an RF communication system is shown in FIG. 3. FIG. 3 is a block diagram of a portion of a communication system 300 including at least two lasers, such as Laser 1 (302) and Laser 2 (304). Each laser 302, 304 has a fixed frequency (wavelength), such as frequency 1 for Laser 1 and frequency 2 for Laser 2. The system 300 further includes a switch 306 and an electro-optical modulator (EOM) 308. The switch 306 receives, as inputs, the laser 302 and the laser 304 and outputs one of the lasers 302, 304 to the EOM 308. The system 300 can, in some examples, include a tuning circuit 310 for controlling the frequencies of the lasers 302, 304.

In operation, the switch 306 switches between the laser 302 and the laser 304 (and any other lasers) as needed to hop the signal transmission at the output 312. Because each of the lasers 302, 304 are operating simultaneously at different fixed frequencies, the system 300 can switch between those different frequencies as quickly as the switch 306 can switch between the lasers 302, 304. However, the cost, size, and weight of the system 300 increases as the number of lasers and other componentry increases, such as the lasers 302, 304, the switch 306, and the tuning circuit 310, used for operation under FHSS. Thus, it may be desirable to utilize a system with a single, frequency tuning scanning laser, such as described in further detail below.

Frequency Tunable Scanning Laser System with a Single Laser

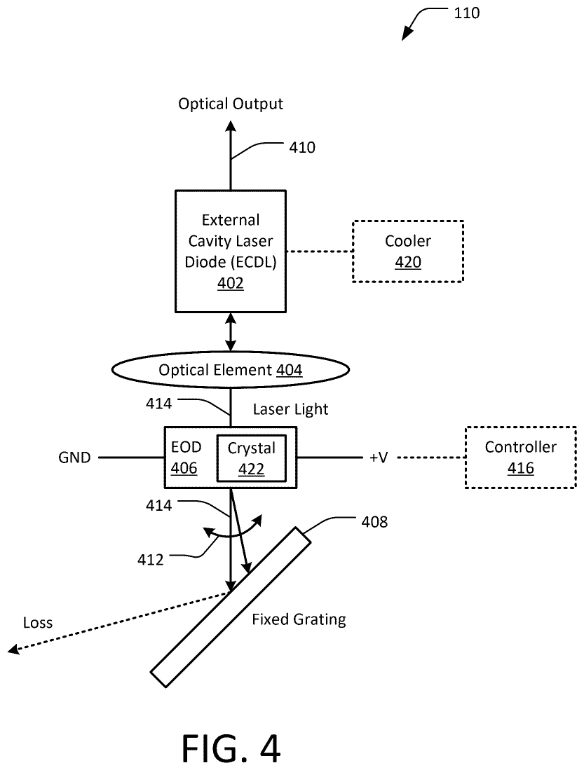

Another example of an RF communication system is shown in FIG. 4. FIG. 4 is a block diagram of the frequency tunable scanning laser system 110 of FIG. 1, in accordance with an example of the present disclosure. The RF transmitter 112 is configured to generate the signal 102 at different radio frequencies. For example, the signal 102 is encoded in the RF using an FHSS technique, where the frequency of the signal 102 is changed over the course of the communication.

In contrast to the example of the laser communication system 300 of FIG. 3, in this example the frequency tunable scanning laser system 110, which can be part of the atomic receiver 104 of FIG. 1, includes a high-stability, external cavity diode laser (ECDL) 402 configured to output laser light, an optical element 404, an EOD 406, and a fixed, frequency selective grating 408. That is, the frequency tunable scanning laser system 110 of FIG. 4 utilizes a single ECDL instead of multiple lasers, such as shown in FIG. 3.

In some examples, the ECDL 402 includes a dual facet gain chip that permits direct power outcoupling. The ECDL 402 has an optical output 410 (e.g., via fiber optics). The laser of the ECDL 402 can be, for example, a continuous wave laser or a quasi-continuous wave laser that is used as a tunable light source. The EOD 406 includes a crystal 422 that is at least partially transparent and configured to deflect the laser light passing through the EOD.

The laser diode generally outputs a relatively wide spectrum of light, although it is not used as a swept light source. The grating 408 reflects a relatively narrow spectrum of light back along the incident light beam, and thus acts as a frequency selection filter, where the frequency of the light reflected from the grating 408 depends on the angle of incidence of the light upon the grating 408. For example, the grating 408 can be a fixed (i.e., non-rotatable), wavelength-sensitive diffraction grating configured to reflect at least a portion of the laser light 414 deflected by the EOD 406 (e.g., a specific wavelength of the laser light within several nanometers) back to the ECDL 402 via the EOD 406 at a tunable frequency. In this manner, the EOD 406 can be controlled to deflect the light so as to change the angle of incidence of the light upon the grating 408 thereby controlling the frequency of the light reflected from the grating 408.

The EOD 406 has power terminals+V and GND for applying a voltage to the EOD. The voltage +V determines an amount of deflection 412 of laser light 414 passing through the EOD 406 via the optical element 404. The amount of deflection 412 of the laser light 414 determines the frequency of the laser light 414 that is returned to the ECDL 402 via the EOD 406 and the optical element 404. In this manner, the frequency of the laser light at the optical output 410 can be varied by changing the voltage V applied to the crystal 422 in the EOD 406. The tunable frequency of the laser light reflected by the grating 408 is a function of an angle of incidence of the laser light 414 on the grating 408, as defined by the optical properties of the grating surface, and the angle of incidence of the laser light 414 on the grating 408 is based on an amount of deflection 412 of the laser light 414 by the EOD 406. The amount of deflection 412 of the EOD 406 is a function of the length of the crystal and the voltage applied to the crystal.

In some examples, the crystal 422 of the EOD 406 includes a lithium tantalate (LTA) crystal, which has been found to enable the ECDL 402 to achieve fast frequency tuning and stable operation. An LTA crystal can provide a relatively high amount of deflection 412 and stability using a relatively short crystal using a relatively low voltage range. For example, the LTA crystal can provide an approximately 2 nm swing using+/−450 volts. In some examples, the ECDL 402 includes a gain chip with dual partially reflecting facets. In some examples, the optical element 404 includes a collimating lens configured to collimate the laser light 414. In some examples, the frequency tunable scanning laser system 110 is configured to output the laser light at each of a plurality of different tunable frequencies. In some examples, the frequency tunable scanning laser system 110 can change wavelengths of approximately 1.7 nm, repeatedly return to the frequency from which it hopped without hysteresis greater than the drift of an unlocked, free-running ECDL of within approximately 30 MHz, and make the transitions with a 10% to 90% rise time of less than 560 nano seconds. The laser can sustain fixed DC offset deflections while maintaining stable operation on the order of minutes with a frequency drift on order of 1.5 MHz/second.

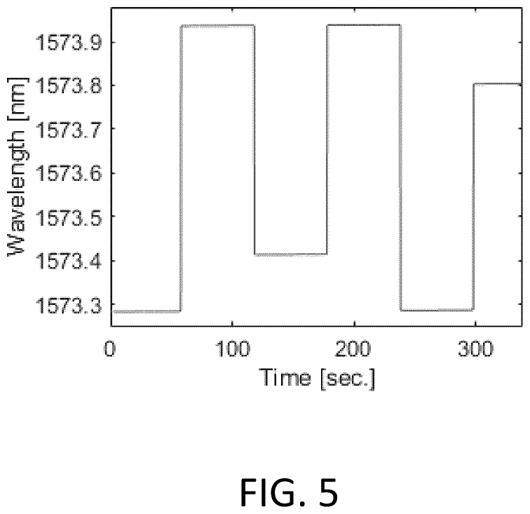

FIG. 5 is a graph showing an example output of the frequency tunable scanning laser system 110, where the narrow linewidth frequency (vertical axis) is changed quickly and remains stable after changing (horizontal axis). Such performance can be achieved using an LTA crystal or another similar crystal.

In some examples, the frequency tunable scanning laser system 110 includes a controller 416 configured to control the tunable frequency by causing the EOD 406 to vary the amount of deflection of the laser light 414 passing through the EOD 406. In some examples, the controller is configured to output a voltage (e.g., +V) to the EOD, where the amount of deflection 412 of the laser light passing through the EOD is a function of the voltage (e.g., the greater the voltage, the greater the amount of deflection 412).

In some examples, the frequency tunable scanning laser system 110 includes a thermoelectric cooler 420 configured to cool the ECDL 402.

In some examples, a length of the EOD 406 is less than six centimeters.

In some examples, the portion of the laser light reflected by the grating 408 includes a first-order diffracted beam.

In some examples, the transmitter 104 includes a radio frequency (RF) transmitter with the frequency tunable scanning laser system 110, where the tunable frequency is a radio frequency.

### Frequency Tunable Scanning Laser Communication System Methodology

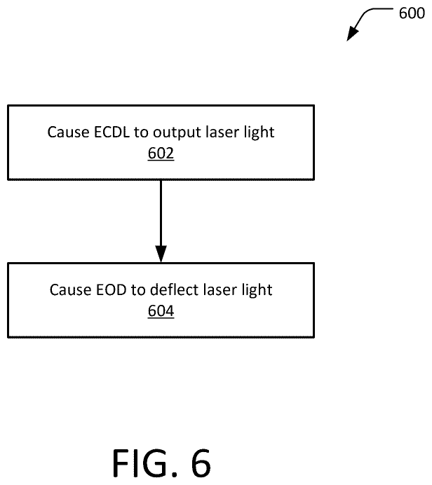

FIG. 6 is a block diagram of a communications method 600 using the frequency tunable scanning laser system 110 of FIG. 4, in accordance with an example of the present disclosure. The method 600 includes causing 602 an external cavity diode laser (ECDL) configured to output laser light, and causing 604 an electro-optic deflector (EOD) to deflect the laser light to a fixed, wavelength-sensitive diffraction grating. The EOD is at least partially transparent to the laser light passing through the EOD. The grating is configured to reflect at least a portion of the laser light deflected by the EOD back to the ECDL via the EOD at a tunable frequency. The tunable frequency is a function of an angle of incidence of the laser light on the grating, and the angle of incidence is based on an amount of deflection of the laser light by the EOD.

Some examples can be implemented, for example, using a machine readable medium or article that stores a set of instructions that, when executed by a machine, causes the machine to perform a method, process, and/or operations in accordance with the examples described herein. Such a machine can include, for example, any suitable processing platform, computing platform, computing device, processing device, computing system, processing system, computer, process, or the like, and can be implemented using any suitable combination of hardware and/or software. The machine readable medium or article can include, for example, any suitable type of memory unit, memory device, memory article, memory medium, storage device, storage article, storage medium, and/or storage unit, such as memory, removable or non-removable media, erasable or non-erasable media, writeable or rewriteable media, digital or analog media, hard disk, floppy disk, compact disk read only memory (CD-ROM), compact disk recordable (CD-R) memory, compact disk rewriteable (CD-RW) memory, optical disk, magnetic media, magneto-optical media, removable memory cards or disks, various types of digital versatile disk (DVD), a tape, a cassette, or the like. The instructions can include any suitable type of code, such as source code, compiled code, interpreted code, executable code, static code, dynamic code, encrypted code, and the like, implemented using any suitable high level, low level, object oriented, visual, compiled, and/or interpreted programming language.

Unless specifically stated otherwise, it will be appreciated that terms such as “processing,” “computing,” “calculating,” and “determining” refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system.

The terms “circuit” or “circuitry” can include, for example, hardwired circuitry, programmable circuitry, such as computer processors comprising one or more individual instruction processing cores, state machine circuitry, and/or firmware that stores instructions executed by programmable circuitry. The circuitry can include a processor and/or controller configured to execute one or more instructions to perform one or more operations described herein. The instructions can be implemented as, for example, an application, software, firmware, etc., configured to cause the circuit or circuitry to perform any of the operations or functions described herein. Software can be implemented as a software package, code, instructions, instruction sets and/or data recorded on a computer-readable storage device. Software can be implemented to include any number of processes, and processes, in turn, can be implemented to include any number of threads, etc., in a hierarchical fashion. Firmware can be implemented as code, instructions or instruction sets and/or data that are hard-coded (e.g., nonvolatile) in memory devices. The circuit or circuitry can be implemented as part of a larger system, for example, an integrated circuit (IC), an application-specific integrated circuit (ASIC), a system-on-a-chip (SoC), desktop computers, laptop computers, tablet computers, servers, smartphones, etc. Other examples can be implemented as software executed by a programmable control device. In such cases, the terms “circuit” or “circuitry” are intended to include a combination of software and hardware such as a programmable control device or a processor capable of executing the software. As described herein, various examples can be implemented using hardware elements, software elements, or any combination thereof. Examples of hardware elements can include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, and/or chip sets.

### Further Example Examples

The following examples pertain to further examples, from which numerous permutations and configurations will be apparent.

Example 1 provides a frequency tunable scanning laser system comprising an external cavity diode laser (ECDL) configured to output laser light; an electro-optic deflector (EOD) being at least partially transparent and configured to deflect the laser light passing through the EOD; and a fixed, wavelength-sensitive diffraction grating configured to reflect at least a portion of the laser light deflected by the EOD back to the ECDL via the EOD at a tunable frequency, the tunable frequency being a function of an angle of incidence of the laser light on the grating, the angle of incidence being based on an amount of deflection of the laser light by the EOD.

Example 2 includes the subject matter of Example 1, wherein the EOD includes a lithium tantalate (LTA) crystal, or a crystal configured to have hysteresis not greater than the drift of an unlocked, free-running ECDL within 30 MHz, or a crystal configured to have hysteresis not greater than a frequency drift of approximately 1.5 MHz/second.

Example 3 includes the subject matter of Examples 1 or 2, wherein the ECDL includes a gain chip with dual partially reflecting facets.

Example 4 includes the subject matter of any one of Examples 1-3, further comprising a collimating lens configured to collimate the laser light.

Example 5 includes the subject matter of any one of Examples 1-4, wherein the ECDL is configured to output the laser light at each of a plurality of different tunable frequencies.

Example 6 includes the subject matter of any one of Examples 1-5, further comprising a controller configured to control the tunable frequency by causing the EOD to vary the amount of deflection of the laser light passing through the EOD, wherein the EOD is configured to maintain a steady, fixed deflection amount.

Example 7 includes the subject matter of Example 6, wherein the tunable frequency changes over multiple nanometers within one microsecond.

Example 8 includes the subject matter of Examples 7 or 8, wherein the controller is configured to output a voltage to the EOD, wherein the amount of deflection of the laser light passing through the EOD is a function of the voltage.

Example 9 includes the subject matter of any one of Examples 1-8, wherein the laser light has low phase noise.

Example 10 includes the subject matter of any one of Examples 1-9, further comprising a thermoelectric cooler configured to cool the ECDL.

Example 11 includes the subject matter of any one of Examples 1-10, wherein a length of the EOD is less than six centimeters.

Example 12 includes the subject matter of any one of Examples 1-11, wherein the portion of the laser light reflected by the grating includes a first-order diffracted beam.

Example 13 provides a radio frequency receiver comprising the tunable scanning laser system of claim 1, wherein the tunable frequency is a laser wavelength.

Example 14 provides a communication system comprising a processor; a laser module configured to output laser light; an electro-optic deflector (EOD) coupled to the processor, the EOD being at least partially transparent and configured to deflect the laser light passing through the EOD; and a fixed, wavelength-sensitive diffraction grating configured to reflect at least a portion of the laser light deflected by the EOD back to the laser module via the EOD at a tunable frequency, the tunable frequency being a function of an angle of incidence of the laser light on the grating, the angle of incidence being based on an amount of deflection of the laser light by the EOD as controlled by the processor.

Example 15 includes the subject matter of Example 14, wherein the EOD includes a lithium tantalate (LTA) crystal, or a crystal configured to have hysteresis not greater than the drift of an unlocked, free-running ECDL within 30 MHz, or a crystal configured to have hysteresis not greater than a frequency drift of approximately 1.5 MHz/second.

Example 16 includes the subject matter of Examples 14 or 15, wherein the laser module includes a gain chip with dual partially reflecting facets.

Example 17 includes the subject matter of any one of Examples 14-16, wherein the system is configured to output the laser light at each of a plurality of different tunable frequencies.

Example 18 provides a communications method, the method comprising causing an external cavity diode laser (ECDL) configured to output laser light; causing an electro-optic deflector (EOD) to deflect the laser light to a fixed, wavelength-sensitive diffraction grating, the EOD being at least partially transparent to the laser light passing through the EOD, the grating configured to reflect at least a portion of the laser light deflected by the EOD back to the ECDL via the EOD at a tunable frequency, the tunable frequency being a function of an angle of incidence of the laser light on the grating, the angle of incidence being based on an amount of deflection of the laser light by the EOD.

Example 19 includes the subject matter of Example 18, wherein the EOD includes a lithium tantalate (LTA) crystal, or a crystal configured to have hysteresis not greater than the drift of an unlocked, free-running ECDL within 30 MHz, or a crystal configured to have hysteresis not greater than a frequency drift of approximately 1.5 MHz/second.

Example 20 includes the subject matter of Examples 18 or 19, further comprising changing the angle of incidence by causing the EOD to change the amount of deflection of the laser light.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A frequency tunable scanning laser system comprising:
an external cavity diode laser (ECDL) configured to output laser light;
an electro-optic deflector (EOD) being at least partially transparent and configured to deflect the laser light passing through the EOD; and
a fixed, wavelength-sensitive diffraction grating configured to reflect at least a portion of the laser light deflected by the EOD back to the ECDL via the EOD at a tunable frequency, the tunable frequency being a function of an angle of incidence of the laser light on the grating, the angle of incidence being based on an amount of deflection of the laser light by the EOD.

2. The frequency tunable scanning laser system of claim 1, wherein the EOD includes a lithium tantalate (LTA) crystal, or a crystal configured to have hysteresis not greater than a frequency drift of approximately 1.5 MHz/second.

3. The frequency tunable scanning laser system of claim 1, wherein the ECDL includes a gain chip with dual partially reflecting facets.

4. The frequency tunable scanning laser system of claim 1, further comprising a collimating lens configured to collimate the laser light.

5. The frequency tunable scanning laser system of claim 1, wherein the ECDL is configured to output the laser light at each of a plurality of different tunable frequencies.

6. The frequency tunable scanning laser system of claim 1, further comprising a controller configured to control the tunable frequency by causing the EOD to vary the amount of deflection of the laser light passing through the EOD, wherein the EOD is configured to maintain a steady, fixed deflection amount.

7. The frequency tunable scanning laser system of claim 6, wherein the tunable frequency changes over multiple nanometers within one microsecond.

8. The frequency tunable scanning laser system of claim 6, wherein the controller is configured to output a voltage to the EOD, wherein the amount of deflection of the laser light passing through the EOD is a function of the voltage.

9. The frequency tunable scanning laser system of claim 1, further comprising a thermoelectric cooler configured to cool the ECDL.

10. The frequency tunable scanning laser system of claim 1, wherein a length of the EOD is less than six centimeters.

11. The frequency tunable scanning laser system of claim 1, wherein the portion of the laser light reflected by the grating includes a first-order diffracted beam.

12. A radio frequency receiver comprising the tunable scanning laser system of claim 1, wherein the tunable frequency is a laser wavelength.

13. A communication system comprising:
a processor;
a laser module configured to output laser light;
an electro-optic deflector (EOD) coupled to the processor, the EOD being at least partially transparent and configured to deflect the laser light passing through the EOD; and
a fixed, wavelength-sensitive diffraction grating configured to reflect at least a portion of the laser light deflected by the EOD back to the laser module via the EOD at a tunable frequency, the tunable frequency being a function of an angle of incidence of the laser light on the grating, the angle of incidence being based on an amount of deflection of the laser light by the EOD as controlled by the processor.

14. The system of claim 13, wherein the EOD includes a lithium tantalate (LTA) crystal, or a crystal configured to have hysteresis not greater than a frequency drift of approximately 1.5 MHz/second.

15. The system of claim 13, wherein the laser module includes a gain chip with dual partially reflecting facets.

16. The system of claim 13, wherein the system is configured to output the laser light at each of a plurality of different tunable frequencies.

17. A communications method, the method comprising:
causing an external cavity diode laser (ECDL) configured to output laser light; and
causing an electro-optic deflector (EOD) to deflect the laser light to a fixed, wavelength-sensitive diffraction grating, the EOD being at least partially transparent to the laser light passing through the EOD, the grating configured to reflect at least a portion of the laser light deflected by the EOD back to the ECDL via the EOD at a tunable frequency, the tunable frequency being a function of an angle of incidence of the laser light on the grating, the angle of incidence being based on an amount of deflection of the laser light by the EOD.

18. The method of claim 17, wherein the EOD includes a lithium tantalate (LTA) crystal, or a crystal configured to have hysteresis not greater than a frequency drift of approximately 1.5 MHz/second.

19. The method of claim 17, further comprising changing the angle of incidence by causing the EOD to change the amount of deflection of the laser light.

20. The method of claim 17, wherein the ECDL includes a gain chip with dual partially reflecting facets.
